(19) United States
(12) Patent Application Publication
(10) Pub. No.: US 2019/0264349 A1
(43) Pub. Date: Aug. 29, 2019

(54) METHOD FOR MANUFACTURING CRYSTAL INGOT

(71) Applicant: FUJIAN JING' AN OPTOELECTRONICS CO., LTD, Quanzhou City (CN)

(72) Inventors: Pin-Hui HSIEH, Quanzhou City (CN); Zhongwei HU, Quanzhou City (CN); Wu-Ching LIN, Quanzhou City (CN); Po-Fan LAI, Quanzhou City (CN); Guifen LIAO, Quanzhou City (CN)

(73) Assignee: FUJIAN JING' AN OPTOELECTRONICS CO., LTD, Quanzhou City (CN)

(21) Appl. No.: 16/398,732

(22) Filed: Apr. 30, 2019

Related U.S. Application Data
(63) Continuation-in-part of application No. PCT/CN2017/097849, filed on Aug. 17, 2017.

(30) Foreign Application Priority Data
Oct. 31, 2016 (CN) 201610928820.6

(51) Int. Cl. C30B 33/02; C30B 29/36; C30B 29/42; C30B 29/20

(52) U.S. Cl. CPC C30B 33/02; C30B 29/20; C30B 29/42; C30B 29/36

(57) ABSTRACT

A method for manufacturing a crystal ingot includes the steps of forming a crystal boule, cutting the crystal boule so as to obtain a crystal ingot from the crystal boule, and subjecting the crystal ingot to an annealing treatment which includes a heating stage, a constant temperature stage and a cooling stage.

### CROSS-REFERENCE TO RELATED APPLICATION

This application is a continuation-in-part application of PCT International Application No. PCT/CN2017/097849 filed on Aug. 17, 2017, which claims priority of Chinese Invention Patent Application No. 201610928820.6, filed on Oct. 31, 2016. The entire content of each of the international and Chinese patent applications is incorporated herein by reference.

### FIELD

The disclosure relates to a method for manufacturing a crystal ingot, particularly to a method for manufacturing a crystal ingot which involves annealing a crystal ingot after the crystal ingot is obtained from a crystal boule.

### BACKGROUND

Certain single crystalline materials (e.g., sapphire (α-Al₂O₃) crystal) have several excellent properties such as high hardness, high melting point, good light permeability, good thermal and chemical stability, etc., and thus are widely applied in national defense, aerospace, semiconductor industry and making articles for daily use. The single crystalline materials may be used as a substrate in semiconductor electronics such as light-emitting diodes (LEDs). For example, sapphire crystal is widely used as a substrate in semiconductor illumination device. When the sapphire substrate is used in blue LEDs, the quality of the sapphire substrate greatly affects the epitaxial growth of a gallium nitride (GaN) layer on the sapphire substrate and the performance and yield of the blue LEDs. Therefore, the quality of the substrate is essential for the production of high quality LEDs.

The three main methods of forming the crystal ingot include: the Kyropoulos method, the heat-exchanger method (HEM) and the edge-defined film-fed growth (EFG) method.

Chinese Invention Patent Publication No. CN 102560631 A discloses a method of manufacturing a sapphire crystal, in which an in-situ annealing procedure was carried out in a crystal growth furnace before a sapphire crystal boule is cut into at least one sapphire crystal ingot. Thereafter, the annealed sapphire crystal boule is cut to form the sapphire crystal ingot. Since the sapphire crystal ingot is obtained by drilling or cutting the sapphire crystal boule using a tungsten steel blade, internal residual stress may be generated in the sapphire crystal ingot during the drilling or cutting procedure.

It should be noted that, during the growth process, a large temperature gradient might be generated in the crystal boule due to differences of heat flow, and thus a plurality of crystal ingots cut from a single crystal boule might have internal residual stress that varies thereamong.

The annealing procedure may also be performed after the sapphire crystal ingot is sliced into sapphire wafers (i.e., the annealing procedure is carried out on the sapphire wafers). However, the annealing procedure might exert various effects on the sapphire wafers, which may result in inconsistent properties among the sapphire wafers.

### SUMMARY

Therefore, an object of the disclosure is to provide a method for manufacturing crystal ingot that can alleviate at least one of the drawbacks of the prior art.

According to the disclosure, a method for manufacturing a crystal ingot includes the steps of:

(A)forming a crystal boule;

(B)cutting the crystal boule so as to obtain a crystal ingot from the crystal boule; and

(C)subjecting the crystal ingot to an annealing treatment;

wherein the annealing treatment includes a heating stage, a constant temperature stage and a cooling stage.

### BRIEF DESCRIPTION OF THE DRAWINGS

Other features and advantages of the present disclosure will become apparent in the following detailed description of the embodiments with reference to the accompanying drawings, of which:

FIG. 1 is a schematic view illustrating consecutive steps of a first embodiment of a method for manufacturing a crystal ingot according to the present disclosure;

FIG. 2 is a graph illustrating a heating stage, a constant temperature stage and a cooling stage of an annealing treatment of the first embodiment;

FIG. 3 is a graph illustrating ratio of sapphire wafers of E1, E2 and CE versus warp values;

FIG. 4 is a graph illustrating ratio of the sapphire wafers of E1, E2 and CE versus bow values;

FIG. 5 is a graph illustrating standard deviation of luminescence wavelengths of light-emitting diodes (LED) chips containing patterned sapphire wafers of E1, E2 and CE;

FIG. 6 is a box-and-whisker dot plot illustrating fluctuations of bow values in the sapphire wafers of E1, E2 and CE; and

FIG. 7 is a graph illustrating changes in ratio of average color temperature values of the LEDs containing the patterned sapphire wafers of E1, E2 and CE.

### DETAILED DESCRIPTION

Before the present disclosure is described in greater detail, it should be noted that where considered appropriate, reference numerals or terminal portions of reference numerals have been repeated among the figures to indicate corresponding or analogous elements, which may optionally have similar characteristics.

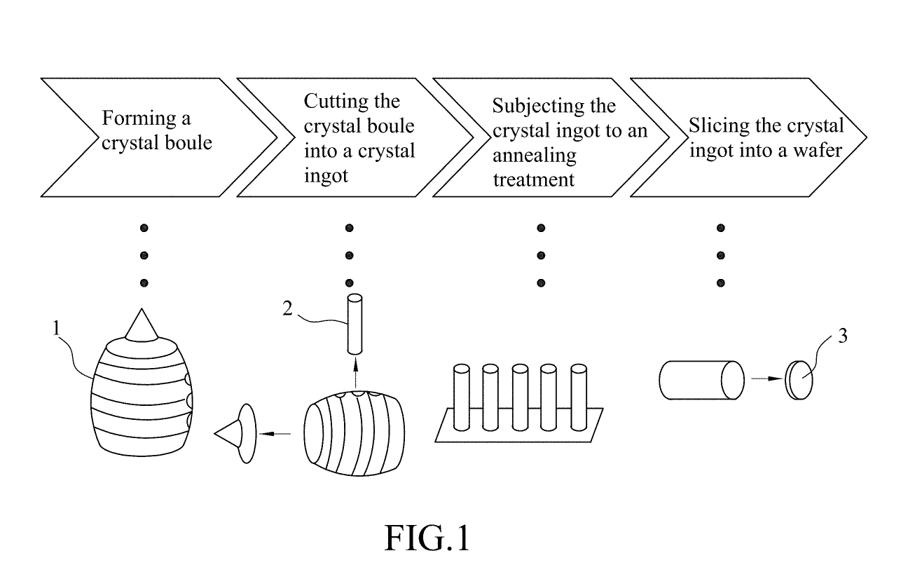

Referring to FIG. 1, a first embodiment of a method for manufacturing a crystal ingot of the present disclosure includes the following Steps A to C. In this embodiment, the crystal ingot is a sapphire crystal ingot.

In Step A, a seed crystal is grown into a crystal boule 1 in a crystal growth furnace (not shown in the figure) . The crystal boule 1 may be formed using a method well-known in the art, for example, the Kyropoulos method, the heat-exchanger method (HEM) and the edge-defined film-fed growth (EFG) method, etc. In this embodiment, the Kyropoulos method is used, in which the seed crystal with a precise orientation is dipped into molten alumina (i.e., source) in a crucible and then slowly pulled upwards. During growth of the crystal, temperature gradient in the crucible should be strictly controlled so as to control the growth rate. The temperature gradient will become more complicated as the volume of the crystal increases. In addition, internal residual stress may be generated in the thus formed crystal boule. As long as the crystal boule does not crack due to excessive internal residual stress, the growth period is shortened as much as possible to reduce the manufacturing cost.

In Step B, after the crystal boule 1 is taken out from the crystal growth furnace, the crystal boule 1 is rapidly cut using a tungsten steel blade so as to obtain a crystal ingot 2. In certain embodiments, the crystal boule 1 may be cut to obtain a plurality of the crystal ingots 2.

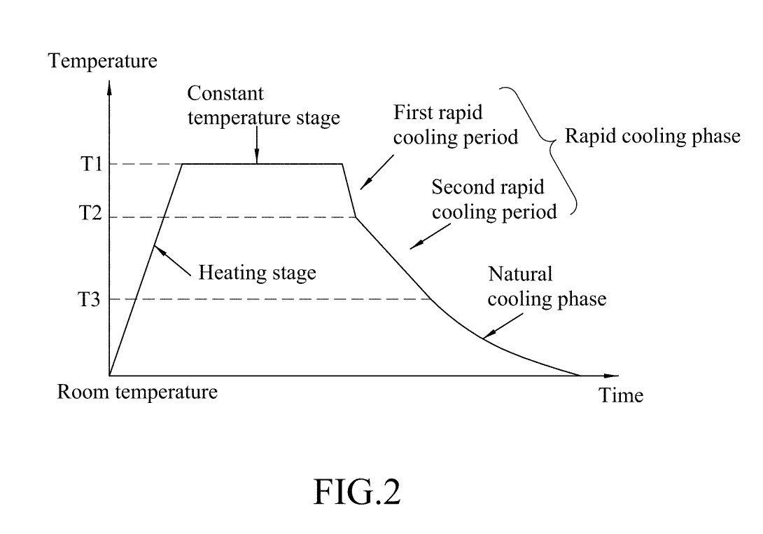

In Step C, the crystal ingot 2 is placed into an annealing furnace and then subjected to an annealing treatment which includes a heating stage, a constant temperature stage and a cooling stage (see FIG. 2). It should be noted that a plurality of the crystal ingots 2 may be simultaneously placed into the annealing furnace, and the plurality of the crystal ingots 2 may be obtained from a single crystal boule 1 or from a plurality of crystal boules 1.

In the heating stage of the annealing treatment, the crystal ingot 2 may be heated to a maximum temperature (T1) ranging from 1700° C. to 1850° C. In certain embodiments, the maximum temperature of the heating stage is 1800° C. such that the crystal ingot 2 might have a superior crystal density. If the maximum temperature is less than the aforementioned range, atoms of the crystal might not be aligned properly, resulting in a poor annealing effect. In addition, the crystal ingot 2 is heated in an uniform manner to avoid a large temperature difference between the surface and core of the crystal ingot 2, thereby preventing formation of cracks in the crystal ingot 2. The large temperature difference is particularly apparent when a plurality of the crystal ingots 2 having a large diameter, are placed in the annealing furnace. In certain embodiments, a temperature in the heating stage is raised at a rate ranging from 50° C./h to 200° C./h. In certain embodiments, the temperature in the heating stage is raised at a rate ranging from 100° C./h to 200° C./h. When a plurality of the crystal ingots 2 are placed and annealed in the annealing furnace, the temperature in the heating stage is raised at a rate from 50° C./h to 90° C./h. When the rate of the temperature raised is higher than the aforesaid range, internal residual stress might be generated in the crystal ingot 2.

In the constant temperature stage of the annealing treatment, a temperature is maintained constant at the maximum temperature (T1) for a time period. The temperature (i.e., the maximum temperature (T1)) in the constant temperature stage may be maintained constant for a time period ranging from 3 to 32 hours. In certain embodiments, the constant temperature stage is performed for 22 to 32 hours. In an exemplary embodiment, the constant temperature stage is performed for 24 hours.

The cooling stage of the annealing treatment includes a rapid cooling phase and a natural cooling phase conducted after the rapid cooling phase. In the rapid cooling phase, the crystal ingot 2 is cooled according to a predetermined temperature. The rapid cooling phase includes a first rapid cooling period and a second rapid cooling period after the first rapid cooling period. The crystal ingot 2 is cooled at a first cooling rate in the first rapid cooling period, and then cooled at a second cooling rate in the second rapid cooling period. The first cooling rate is set to be greater than the second cooling rate for rapidly fixing the atoms of the crystal so as to eliminate the internal residual stress. In the first rapid cooling period, the crystal ingot 2 is cooled to a temperature (T2) ranging from 1150° C. to 1250° C. at the first cooling rate ranging between 150° C./h and 200° C./h. In this embodiment, the crystal ingot 2 is cooled in the first rapid cooling period to a temperature (T2) of 1200° C. In the second rapid cooling period, the crystal ingot 2 is cooled to a temperature (T3) ranging from 350° C. to 450° C. at the second cooling rate ranging between 50° C./h and 100° C./h. In this embodiment, the crystal ingot 2 is cooled in the second rapid cooling period to a temperature (T3) of 400° C. at second cooling rate of 80° C./h. In the natural cooling phase, the crystal ingot 2 is exposed to air at room temperature. Since the second rapid cooling period and the natural cooling phase do not require a large amount of energy, manufacturing cost of the crystal ingot 2 can be reduced.

A second embodiment of a method for manufacturing a crystal ingot according to the present disclosure is similar to that of the first embodiment, with a few exceptions in Step C (i.e., annealing treatment). In the second embodiment, the crystal ingot is a silicon carbide crystal ingot. In the heating stage, a temperature is raised at a rate ranging from 50° C./h to 200° C./h, and the crystal ingot is heated to a maximum temperature ranging from 1700° C. to 1800° C. because silicon carbide will be dissolved at a temperature approximately 1850° C. In the constant temperature stage, the temperature ranging from 1700° C. to 1800° C. is maintained constant for a time period ranging from 3 to 32 hours. In the rapid cooling stage, the crystal ingot is cooled to a temperature ranging from 350° C. to 450° C. at a cooling rate ranging between 50° C./h and 200° C./h.

A third embodiment of a method for manufacturing a crystal ingot according to the present disclosure is similar to that of the second embodiment, except that the crystal ingot is a gallium arsenide crystal ingot and the heating stage of the annealing treatment is performed at a lower temperature. In the third embodiment, since gallium arsenide has a melting temperature of 1238° C., the maximum temperature in the heating stage is set to be ranging from 900° C. to 1150° C. In this embodiment, the crystal ingot is heated to the maximum temperature ranging from 900° C. to 1050° C.

After the annealing treatment, the thus manufactured crystal ingot is sliced to form a wafer 3, which is then heated at a temperature of 1600° C. Subsequently, the wafer 3 is used as a substrate for light-emitting semiconductor devices.

It is found that, after the annealing treatment, impurities present on the surface of the crystal ingot 2 are removed so as to achieve thermal polishing. In addition, the wafer 3 sliced from the annealed crystal ingot 2 exhibits a light transmittance rate of 12% to 13% when it is irradiated by a radiation source having a wavelength of 500 nm. On the other hand, under the same radiation, the wafer sliced from a non-annealed crystal ingot 2 exhibits a relatively low light transmittance rate of 7% to 8%.

The present disclosure will be further described by way of the following examples. However, it should be understood that the following examples are intended solely for the purpose of illustration and should not be construed as limiting the disclosure in practice.

### EXAMPLE 1 (E1)

A sapphire crystal ingot was cut from a crystal boule that was prepared according to the first embodiment of the present disclosure. In this example, the sapphire crystal ingot was heated with a temperature rising rate of 60° C./h to a maximum temperature (T1) of 1750° C., which was maintained for 24 hours. After that, the sapphire crystal ingot was cooled to a temperature (T2) of 1200° C. in the first rapid cooling period. Finally, the thus annealed sapphire crystal ingot was sliced into a plurality of sapphire wafers each having a diameter of 10 cm±0.02 cm and a thickness of 645 μm±15 μm, followed by heating at a temperature of 1600° C.

### EXAMPLE 2 (E2)

The procedures and conditions in preparing the sapphire wafers of E2 were similar to those of E1, except that the temperature in the constant temperature stage was maintained constant for a time period of 30 hours.

### COMPARATIVE EXAMPLE (CE)

For preparing the sapphire wafers of CE, a sapphire ingot cut from a crystal boule was directly sliced into a plurality of sapphire wafers without undergoing the aforementioned annealing treatment. Subsequently, the sapphire wafers were heated at a temperature of 1600° C.

### Warping Test

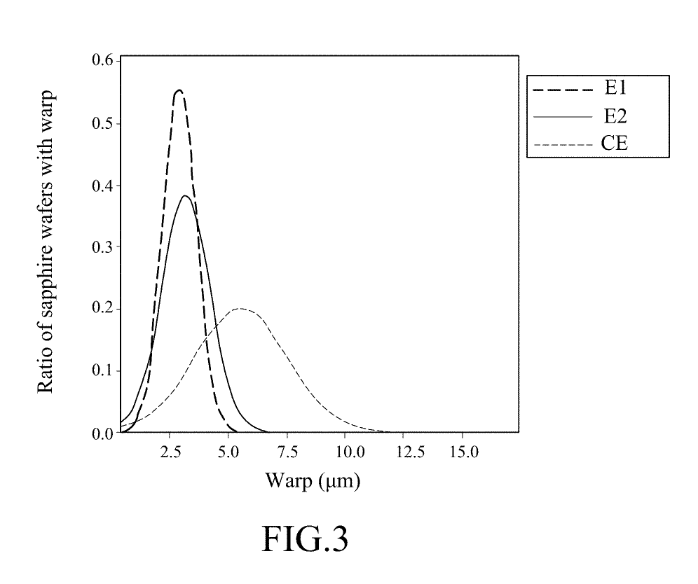

Each of the sapphire wafers of E1, E2 and CE1 was subjected to a warping test based on SEMI MF657-0707. FIG. 3 shows that, in comparison with the sapphire wafers of CE, the sapphire wafers of E1 and E2 have relatively small warps, especially the sapphire wafers of E1. Moreover, the warp difference among the sapphire wafers in each of E1 and E2 is relatively small, i.e., narrow distribution of the warp values.

### Bow Test

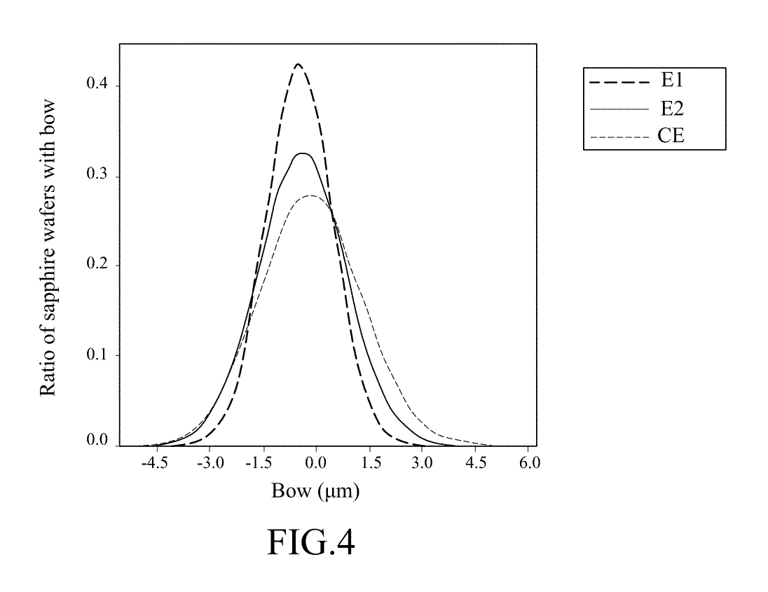

Each of the sapphire wafers of E1, E2 and CE was subjected to a bow test based on SEMI MF534-0707. FIG. 4 shows that, as compared to CE, a relatively high ratio of the sapphire wafers for each of E1 and E2 have bow values that are close to 0 μm.

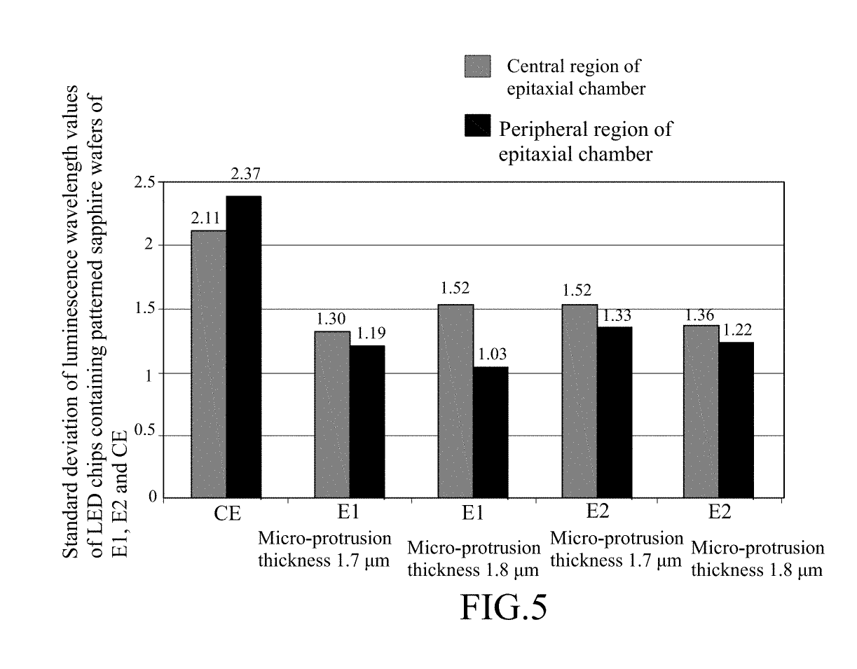

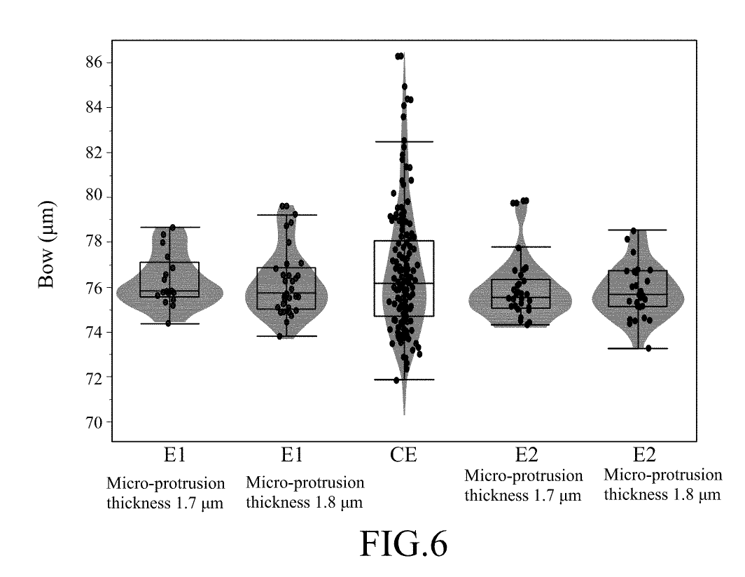

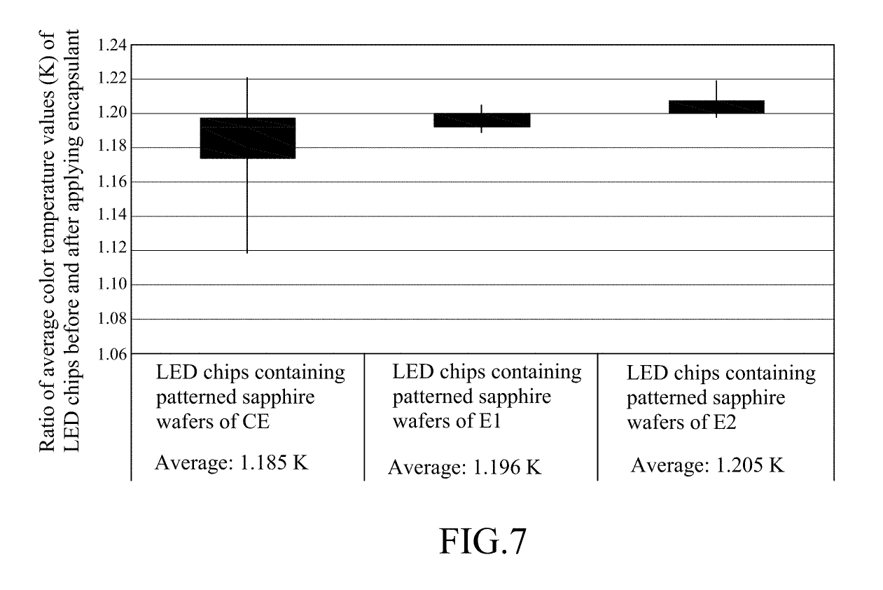

Each of the sapphire wafers of E1 and E2 was patterned to form a plurality of micro-protrusions (with a height of 1.7 μm or 1.8 μm), and was subjected to the bow test. FIG. 6 shows that the patterned sapphire wafers of E1 and E2 have smaller fluctuations of bow values as compared to the sapphire wafers of CE. The patterned sapphire wafers of E1 and E2 were then placed in an epitaxial growth device that includes an epitaxial chamber having a central region and a peripheral region surrounding the central region. For performing epitaxial growth procedure, the patterned sapphire wafers of E1 and E2 were placed in the central region and the peripheral region to form an epitaxial layer unit on each of the patterned sapphire wafers of E1 and E2 so as to obtain an LED chip. Afterwards, an encapsulant was applied to cover each of the epitaxial layer unit. The sapphire wafers of CE were also subjected to the epitaxial growth procedure and then covered with the encapsulants. As shown in FIG. 5, LED chips containing the patterned sapphire wafers of E1 and E2 have smaller standard deviation of luminescence wavelengths as compared to the LED chips containing the sapphire wafers of CE. In addition, FIG. 7 shows that the LED chips containing the patterned sapphire wafers of E1 and E2 have smaller change in ratio of average color temperature values (K) measured before and after the encapsulants were applied. These results indicate that, as compared to the sapphire wafers of CE, the sapphire wafers of E1 and E2 have improved consistency of flatness and are not prone to breakage and edge chipping. Thus, luminescence wavelength and K value among the LED chips containing the substrates made by the method of the embodiment of this disclosure will be relatively constant (i.e., have relatively small variation).

In summary, by virtue of subjecting the crystal ingot 2 to the aforementioned annealing treatment of this disclosure, internal residual stress in the crystal ingot 2 may be reduced so as to improve the consistency of the shape and property of the crystal ingot 2, resulting in improved consistency of the flatness of the wafer 3 (as shown by minimal bow and warp values), which renders the wafer 3 as a suitable substrate for growing the epitaxial layer thereon. Thus, the quality and production yield of the light-emitting semiconductor device may be increased.

In the description above, for the purposes of explanation, numerous specific details have been set forth in order to provide a thorough understanding of the embodiment(s). It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A method for manufacturing a crystal ingot, comprising the steps of:
(A) forming a crystal boule;
(B) cutting the crystal boule so as to obtain a crystal ingot from the crystal boule; and
(C) subjecting the crystal ingot to an annealing treatment;
wherein the annealing treatment includes a heating stage, a constant temperature stage and a cooling stage.

2. The method as claimed in claim 1, wherein, in step (C), a temperature in the heating stage is raised at a rate ranging from 50° C./h to 200° C./h.

3. The method as claimed in claim 1, wherein step (B) includes cutting the crystal boule so as to obtain a plurality of crystal ingots, and in step (C), a temperature in the heating stage is raised at a rate from 50° C./h to 90° C./h.

4. The method as claimed in claim 1, wherein the crystal ingot is selected from the group consisting of a sapphire crystal ingot, a silicon carbide crystal ingot, and a gallium arsenide crystal ingot.

5. The method as claimed in claim 1, wherein the crystal ingot is a sapphire crystal ingot.

6. The method as claimed in claim 5, wherein a temperature in the constant temperature stage is maintained constant, the temperature ranging from 1700° C. to 1850° C.

7. The method as claimed in claim 4, wherein the constant temperature stage is performed for a time period ranging from 3 to 32 hours.

8. The method as claimed in claim 6, wherein the constant temperature phase is performed for a time period ranging from 22 to 32 hours.

9. The method as claimed in claim 1, wherein the cooling stage includes a rapid cooling phase and a natural cooling phase conducted after the rapid cooling phase, in the natural cooling phase, the crystal ingot being exposed to air at room temperature.

10. The method as claimed in claim 9, wherein the rapid cooling phase includes a first rapid cooling period and a second rapid cooling period conducted after the first rapid cooling period, the crystal ingot being cooled at a first cooling rate in the first rapid cooling period, and then cooled at a second cooling rate in the second rapid cooling period, the first cooling rate being greater than the second cooling rate.

11. The method as claimed in claim 10, wherein, in the first rapid cooling period, the crystal ingot is cooled to a temperature ranging from 1150° C. to 1250° C. at the first cooling rate ranging between 150° C./h and 200° C./h, and in the second rapid cooling period, the crystal ingot is cooled to a temperature ranging from 350° C. to 450° C. at the second cooling rate ranging between 50° C./h and 100° C./h.
